(19) United States
(12) Patent Application Publication
(10) Pub. No.: US 2025/0194101 A1
(43) Pub. Date: Jun. 12, 2025

(54) STACKED MRAM WITH SUPER VIA STRUCTURES

(71) Applicant: International Business Machines Corporation, Armonk, NY (US)

(72) Inventors: Pouya Hashemi, Purchase, NY (US); Jim Shih-Chun Liang, Poughkeepsie, NY (US)

(21) Appl. No.: 18/531,074

(22) Filed: Dec. 6, 2023

(51) Int. Cl. H10B 61/00; H10N 50/01; H10N 50/20; H10N 50/80

(52) U.S. Cl. CPC H10B 61/00; H10N 50/01; H10N 50/20; H10N 50/80

(57) ABSTRACT

A memory structure is provided that includes a first tier including a plurality of first magnetoresistive random access memory (MRAM) cells, and a second tier including a plurality of second MRAM cells. Each second MRAM cell is located above and horizontally offset from each of the first MRAM cells. Each first MRAM cell is sandwiched between a bottom electrically conductive via structure and a top electrically conductive super via structure, and each second MRAM cell is sandwiched between a bottom electrically conductive super via structure and a top electrically conductive via structure.

### BACKGROUND

The present application relates to semiconductor technology, and more particularly to non-volatile random access memory.

Magnetoresistive random access memory (MRAM) is a non-volatile random access memory technology in which data is stored by magnetic storage elements. These elements are typically formed from two ferromagnetic plates, each of which can hold a magnetization, separated by a thin dielectric layer (i.e., a tunnel barrier layer). One of the two plates (i.e., the magnetic reference or pinned layer) is a magnet whose magnetic moment direction is set to a particular direction; the other plate's (i.e., the magnetic free layer's) magnetization can be changed in at least two different directions, representing different digital states such as 0 and 1 for memory applications. In MRAMs, such elements may be referred to as a magnetic tunnel junction (MTJ) structure. In a typical MTJ structure, the magnetization of the magnetic reference layer is fixed in one direction (say pointing up), while the direction of the magnetic free layer can be “switched” by some external forces, such as a magnetic field or a spin-transfer torque generating charge current. A smaller current (of either polarity) can be used to read the resistance of the device, which depends on the relative orientations of the magnetizations of the magnetic free layer and the magnetic reference layer. The resistance is typically higher when the magnetizations are anti-parallel, and lower when they are parallel (though this can be reversed, depending on the material).

One type of MRAM that can use a MTJ structure is spin-transfer torque (STT) MRAM. STT MRAM has the advantages of lower power consumption and better scalability over conventional MRAM which uses magnetic fields to flip the active elements. In STT MRAM, spin-transfer torque is used to flip (switch) the orientation of the magnetic free layer. For an STT MRAM device, a current passing through the MTJ structure is used to switch, or “write” the bit-state of the MTJ memory element. A current passing down through the MTJ structure makes the magnetic free layer parallel to the magnetic reference layer, while a current passed up through the MTJ structure makes the magnetic free layer anti-parallel to the magnetic reference layer.

### SUMMARY

A memory structure is provided that includes a first tier including a plurality of first MRAM cells, and a second tier including a plurality of second MRAM cells. Each second MRAM cell is located above and horizontally offset from each of the first MRAM cells. Each first MRAM cell is sandwiched between a bottom electrically conductive via structure and a top electrically conductive super via structure, and each second MRAM cell is sandwiched between a bottom electrically conductive super via structure and a top electrically conductive via structure. In the present application, an electrically conductive super via structure has a height, i.e., vertical length, which is greater than a height of a normal electrically conductive via structure.

In one aspect of the present application, a memory structure is provided. In one embodiment of the present application, the memory structure includes a first tier including a plurality of first MRAM cells, wherein each first MRAM cell of the plurality of first MRAM cells has a bottom surface in electrical contact with a first electrically conductive via structure and a top surface in electrical contact with a second electrically conductive super via structure. The memory structure further includes a second tier including a plurality of second MRAM cells, wherein each second MRAM cell of the plurality of second MRAM cells is located above and horizontally offset from each of the first MRAM cells of the plurality of first MRAM cells, wherein each second MRAM cell of the plurality of second MRAM cells has a bottom surface in electrical contact with a first electrically conductive super via structure and a top surface in electrical contact with a second electrically conductive via structure.

In another aspect of the present application, a method of forming a memory structure is provided. In one embodiment, the method includes forming an interconnect level having a plurality of electrically conductive wiring structures embedded in an interconnect dielectric layer. Next, a first electrically conductive structure is formed in electrical contact with every other electrically wiring structure of the plurality of electrically conductive wiring structures. A plurality of first MRAM cells in a first tier are then formed, wherein each first MRAM cell of the plurality of first MRAM cells has a bottom surface in electrical contact with one of the first electrically conductive via structures. Next, a first electrically conductive super via structure is formed in electrical contact with electrically conductive wiring structures not including the first electrically conductive via structure present thereon. A plurality of second MRAM cells is then formed in a second tier located above the first tier, wherein each second MRAM cell of the plurality of second MRAM cells is located above and horizontally offset from each of the first MRAM cells of the plurality of first MRAM cells. After forming the second MRAM cells, a plurality of second electrically conductive super via structures is formed in electrical contact with a topmost surface of each first MRAM cell of the plurality of first MRAM cells and a plurality of second electrically conductive via structures is formed in electrical contact with a topmost surface of each second MRAM cell of the plurality of second MRAM cells.

### BRIEF DESCRIPTION OF THE DRAWINGS

FIG. 1 is a cross sectional view of an exemplary structure that can be used in accordance with an embodiment of the present application, the exemplary structure including an interconnect level including electrically conductive wiring structures embedded in a first interconnect dielectric layer.

FIG. 2 is a cross sectional view of the exemplary structure shown in FIG. 1 after forming a dielectric capping layer and a second interconnect dielectric layer containing first electrically conductive via structures on top of the interconnect level.

FIG. 3 is a cross sectional view of the exemplary structure shown in FIG. 2 after recessing each of the first electrically conductive via structures.

FIG. 4 is a cross sectional view of the exemplary structure shown in FIG. 3 after forming a first electrode material layer on a surface of the second interconnect dielectric layer and on a surface of each of the recessed first electrically conductive via structures.

FIG. 5 is a cross sectional view of the exemplary structure shown in FIG. 4 after removing the first electrode material layer from the surface of the second interconnect dielectric layer, while maintaining the first electrode material layer on the surface of each of the recessed first electrically conductive via structures, wherein the maintained first electrode material layer provides a first electrode.

FIG. 6 is a cross sectional view of the exemplary structure shown in FIG. 5 after forming a first MTJ stack and a second electrode material layer on top of the second interconnect dielectric layer.

FIG. 7 is a cross sectional view of the exemplary structure shown in FIG. 6 after patterning the second electrode material layer and the first MTJ stack to provide second electrodes and first MTJ structures, respectively, and forming a first encapsulation layer.

FIG. 8 is a cross sectional view of the exemplary structure shown in FIG. 7 after forming a third interconnect dielectric layer.

FIG. 9 is a cross sectional view of the exemplary structure shown in FIG. 8 after forming a first electrically conductive super via structure, and forming a third electrode on a surface of the first electrically conductive super via structure.

FIG. 10 is a cross sectional view of the exemplary structure shown in FIG. 9 after forming a second MTJ structure and a fourth electrode on top of the third electrode, and forming a second encapsulation layer.

FIG. 11 is a cross sectional view of the exemplary structure shown in FIG. 10 after forming a fourth interconnect dielectric layer.

FIG. 12 is a cross sectional view of the exemplary structure shown in FIG. 11 after forming additional interconnect dielectric material on the fourth interconnect dielectric layer, wherein the additional dielectric material and the fourth dielectric layer collectively provide an uppermost interconnect dielectric layer that covers an entirety of the second encapsulation layer including the portion of the second encapsulation layer that is located on top of the fourth electrode, and forming super vias and normal vias in the uppermost interconnect dielectric layer.

FIG. 13 is a cross sectional view of the exemplary structure shown in FIG. 12 after physically exposing each of the second electrodes and the fourth electrodes.

FIG. 14 is a cross sectional view of the exemplary structure shown in FIG. 13 after forming an electrically conductive layer on a surface of the uppermost interconnect dielectric layer and on a physically exposed surface of each of the second electrodes and the fourth electrodes.

FIG. 15 is a cross sectional view of the exemplary structure shown in FIG. 14 after removing the electrically conductive layer from the surface of the uppermost interconnect dielectric layer, while maintaining the electrically conductive layer on the physically exposed surface of each of the second electrodes and the fourth electrodes.

FIG. 16 is a top down view depicting a MRAM array in accordance with an embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 100 deviation in angle.

Ion beam etching (IBE) is the main patterning scheme for MRAM due to the complexity of the MTJ stack which continues to evolve. As MRAM pitch is scaled for advanced nodes, MRAM patterning and reduction of partial shorts in the arrays becomes more challenging due to the limitation of high angle IBE (required to clean the re-sputtered metal on MTJ sidewalls) which is a result of shadowing of neighboring MTJ structures. A solution to the above problem is desirable.

A stacked 1-transistor (1T) 1-MTJ MRAM approach is proposed herein as a solution to the above problem. Notably, in this 1T 1MTJ MRAM approach, the memory array is split into two tiers which doubles the pitch between adjacent MTJ structures on the same tier. This pitch doubling, in turn, mitigates and, in some instances, even eliminates the obstacles associated with cleaning re-sputtered metal on the MTJ structure sidewalls which is typically observed at tight MTJ pitches.

In the memory array of the present application, the doubling of the pitch between neighboring MTJ structures on the same tier provides an improved IBE patterning process window to clean the re-deposited metal on the sidewalls of the MTJ structures which, in turn, can reduce partial shorts in the memory array. Moreover, by maintaining a 1T MTJ design for speed, the MTJ density can be enhanced due to the horizontal offset provided by the second tier MTJ structures. Also, the wiring resistance is maintained in the present application for the first and second tier MTJ structures; a similar access resistance for both tiers is provided. Furthermore, the present application provides reduced litho patterning levels to provide the two tier memory structure.

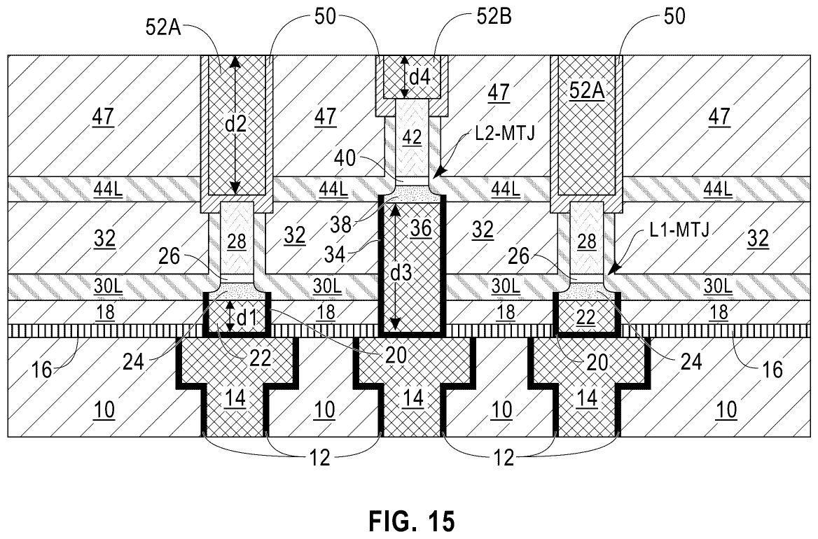

In one aspect of the present application and as is illustrated in FIG. 15, a memory structure is provided. In one embodiment of the present application, the memory structure includes a first tier (L1-MTJ) including a plurality of first MRAM cells, wherein each first MRAM cell of the plurality of first MRAM cells has a bottom surface in electrical contact with a first electrically conductive via structure 22 and a top surface in electrical contact with a second electrically conductive super via structure 52A. The memory structure further includes a second tier (L2-MTJ) including a plurality of second MRAM cells, wherein each second MRAM cell of the plurality of second MRAM cells is located above and horizontally offset from each of the first MRAM cells of the plurality of first MRAM cells, wherein each second MRAM cell of the plurality of second MRAM cells has a bottom surface in electrical contact with a first electrically conductive super via structure 36 and a top surface in electrical contact with a second electrically conductive via structure 52B. Throughout the present application, an electrically conductive via structure is a normal via structure that has a first height (i.e., vertical length), and an electrically conductive super via structure is a via structure having a second height (i.e., vertical length) that is greater than the first height. Such a memory structure exhibits an improved IBE patterning process window to clean the re-deposited metal on the sidewalls of the MTJ structures which, in turn, can reduce partial shorts in the memory array, and the MTJ density can be enhanced due to the horizontal offset provided by the second tier MTJ structures.

In some embodiments of the present application (See, for example, FIG. 15), the first electrically conductive via structure 22 and the first electrically conductive super via structure 36 have bottommost surfaces that are substantially coplanar with each other, and the second electrically conductive super via structure 52A and the second electrically conductive via structure 52B have topmost surfaces that are substantially coplanar with each other. In such embodiments, the wiring distance d1+d2 provided by the combination of the first electrically conductive via structure 22 and the second electrically conductive super via structure 52A, respectively, is substantially equal to the wiring distance d3+d4 provided by the combination of the first electrically conductive super via structure 36 and the second electrically conductive via structure 52B, respectively. In such cases in which substantially equal wiring distances (i.e., d1+d2 substantially equal to d3+d4) are exhibited between the combination of the first electrically conductive via structure 22 and the second electrically conductive super via structure 52A and the combination of the first electrically conductive super via structure 36 and second electrically conductive via structure 52B, the combination of the first electrically conductive via structure 22 and the second electrically conductive super via structure 52A is symmetrical to the combination of the first electrically conductive super via structure 36 and second electrically conductive via structure 52B. The symmetrical nature between the combination of the first electrically conductive via structure 22 and the second electrically conductive super via structure 52A and the combination of the first electrically conductive super via structure 36 and the second electrically conductive via structure 52B maintains equal wiring resistance for the first and second tier MTJ structures. As such, a similar access resistance for both tiers is provided.

In some embodiments of the present application (See, for example, FIG. 15), each first MRAM cell of the plurality of first MRAM cells includes a first electrode 24, a first MTJ structure 26, and a second electrode 28.

In some embodiments of the present application (See, for example, FIG. 15), the first electrode 24 is in electrical contact with the first electrically conductive via structure 22, and the second electrode 28 is in electrical contact with the second electrically conductive super via structure 52A.

In some embodiments of the present application (See, for example, FIG. 15), each second MRAM cell of the plurality of second MRAM cells includes a third electrode 38, a second MTJ structure 40, and a fourth electrode 42.

In some embodiments of the present application (See, for example, FIG. 15), the third electrode 38 is in electrical contact with the first electrically conductive super via structure 36, and the fourth electrode 42 is in electrical contact with the second electrically conductive via structure 52B.

In some embodiments of the present application (See, for example, FIG. 15), the first electrically conductive via structure 22 is in electrical contact with an electrically conductive wiring structure 14, and the first electrically conductive super via structure 36 is in electrical contact with another electrically conductive wiring structure (middle electrically conductive structure 14 shown in FIG. 15).

In some embodiments of the present application (See, for example, FIG. 15), the first electrode 24 and the third electrode 38 both have a topmost surface that is connected to a sidewall by a beveled surface.

In some embodiments of the present application, the first MTJ structure 26 and the second MTJ structure 40 both include a tunnel barrier layer sandwiched between a magnetic reference layer and a magnetic free layer. In some embodiments of the present application, the magnetic free layer is located above the magnetic reference layer. In other embodiments of the present application, the magnetic free layer is located beneath the magnetic reference layer.

In some embodiments of the present application, the memory structure can further include a diffusion barrier liner (see, for example, second diffusion barrier liner 20, third diffusion barrier liner 34 and fourth diffusion barrier liner 50) present along sidewalls of each of the first electrically conductive via structure 22, the first electrically conductive super via structure 36, the second electrically conductive via structure 52B and the second electrically conductive super via structure 52A.

In some embodiments of the present application (See, for example, FIG. 15), the memory structure can further include a first encapsulation liner 30L located adjacent to each first MRAM cell of the plurality of first MRAM cells. In some embodiments of the present application, the memory structure can even further include a second encapsulation liner 44L located adjacent to each second MRAM cell of the plurality of second MRAM cells.

In some embodiments of the present application (See, for example, FIG. 15), the plurality of first MRAM cells is present in an interconnect layer that differs from the plurality of second MRAM cells.

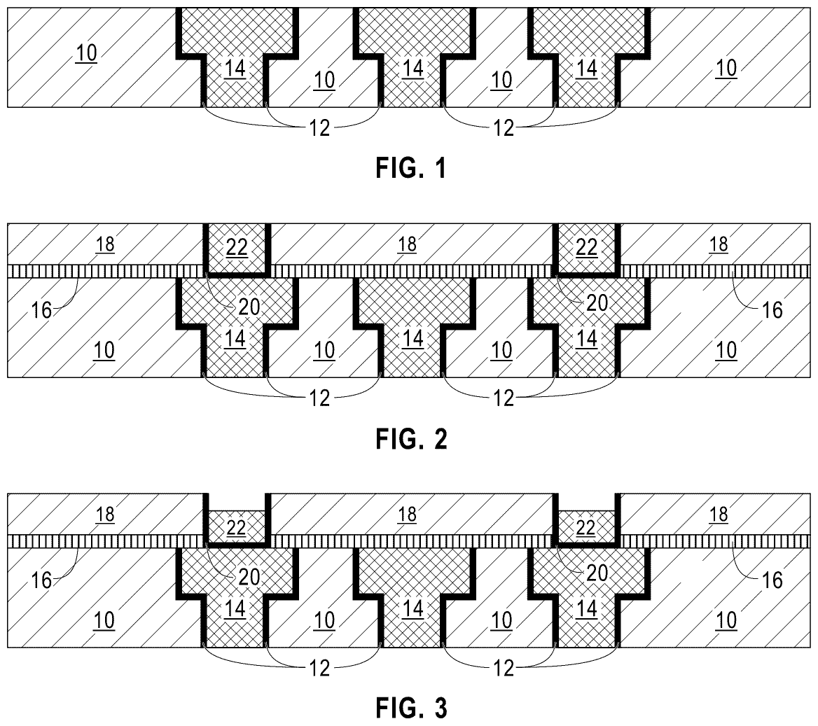

In another aspect of the present application (See, for example, FIGS. 1-15), a method of forming a memory structure is provided. In one embodiment, the method includes forming an interconnect level having a plurality of electrically conductive wiring structures embedded in an interconnect dielectric layer. Next, a first electrically conductive structure is formed in electrical contact with every other electrically wiring structure of the plurality of electrically conductive wiring structures. A plurality of first MRAM cells in a first tier are then formed, wherein each first MRAM cell of the plurality of first MRAM cells has a bottom surface in electrical contact with one of the first electrically conductive via structures. Next, a first electrically conductive super via structure is formed in electrical contact with electrically conductive wiring structures not including the first electrically conductive via structure present thereon. A plurality of second MRAM cells is then formed in a second tier located above the first tier, wherein each second MRAM cell of the plurality of second MRAM cells is located above and horizontally offset from each of the first MRAM cells of the plurality of first MRAM cells. After forming the second MRAM cells, a plurality of second electrically conductive super via structures is formed in electrical contact with a topmost surface of each first MRAM cell of the plurality of first MRAM cells and a plurality of second electrically conductive via structures is formed in electrical contact with a topmost surface of each second MRAM cell of the plurality of second MRAM cells.

These and other aspect of the present application will now be described in greater detail. It is noted that the drawings of the present application illustrate a memory device area in which a memory structure such as, for example, a MRAM array, will be formed. A non-memory device area may be located laterally adjacent to the memory device area illustrated in the drawings of the present application. In the present application, the memory structure will be formed in the back-end-of-the-line (BEOL). The memory structure of the present application can be used in various memory applications including, for example, as a STT MRAM device.

Referring first to FIG. 1, there is illustrated an exemplary structure that can be used in accordance with an embodiment of the present application. The illustrated exemplary structure of FIG. 1 includes an interconnect level including electrically conductive wiring structures 14 embedded in a first interconnect dielectric layer 10. In some embodiments and as is illustrated in FIG. 1, a first diffusion barrier liner 12 can be present along at least the sidewalls of each of the electrically conductive wiring structures 14.

The interconnect level exemplified in FIG. 1 can be located above at least one underlying metal level (not shown) and a front-end-of-the-line (FEOL) level also not shown. In some embodiments, the metal level can be a middle-of-the line (MOL) level. In other embodiments, the metal level can be at least one lower interconnect level of a multi-level interconnect structure. In yet further embodiments, the metal level can be a combination of a MOL level and at least one lower interconnect level of a multi-level interconnect structure. The metal level can include electrically conductive wiring structures embedded in a dielectric material layer. The FEOL level can include a semiconductor substrate having one or more semiconductor devices (such as, for example, transistors) formed thereon. The metal level and the FEOL level can be formed utilizing materials and techniques that are well known to those skilled in the art. So not to obscure the memory structure of the present application, the materials and techniques used in providing the metal level and the FEOL level are not described in the present application.

The first interconnect dielectric layer 10 can be composed of any interconnect dielectric material including, for example, silicon dioxide, silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. The first interconnect dielectric layer 10 can be formed utilizing a deposition process such as, for example, chemical vapor deposition (CVD), plasma enhanced chemical vapor deposition (PECVD) or spin-on coating.

The optional first diffusion barrier liner 12 is composed of a diffusion barrier material such as, for example, Ta, TaN, Ti, TiN, Ru, RuN, RuTa, RuTaN, W, WN or any other material that can serve as a barrier to prevent an electrically conductive material from diffusing there through. The thickness of the first diffusion barrier liner 12 may vary. In one example, the thickness of the first diffusion barrier liner 12 is from 2 nm to 50 nm.

Each of the electrically conductive wiring structures 14 is composed of an electrically conductive metal or an electrically conductive metal alloy. The electrically conductive metal that provides each of the electrically conductive wiring structures 14 can include, for example, copper (Cu), aluminum (Al), tungsten (W), cobalt (Co), ruthenium (Ru), nickel (Ni), iridium (Ir), or rhodium (Rh). An example of an electrically conductive alloy that provides each of the electrically conductive wiring structures 14 includes a Cu—Al alloy. The electrically conductive wiring structures 14 can have a shape of a metal line, a metal via or, as is shown in FIG. 1, a combination of a metal line and a metal via.

The electrically conductive wiring structures 14 can be formed utilizing a damascene process that is well known to those skilled in the art. For example, the damascene process can include forming openings into the first interconnect dielectric layer 10. The openings can be formed by lithography and etching. Lithography includes forming a photoresist material on a layer or stack of material layers that need to be patterned, exposing the photoresist material to a desired pattern of irradiation and thereafter developing the exposed photoresist material utilizing a conventional resist developer. The developed photoresist material has a desired pattern that is then transferred to the layer or stack of material layers that need to be patterned by etching. Etching can include dry etching and/or chemical wet etching. In one embodiment, a dry etch such as, for example, reactive ion etching (RIE), ion beam etching (IBE), plasma etching or any combination thereof can be used to transfer the pattern to the layer or stack of material layers that need to be patterned. In illustrated embodiment, this etch etches through an entirety of the first interconnect dielectric layer 10. In embodiments, this etch can stop within a sub-surface of the first interconnect dielectric layer 10. The developed photoresist material can be removed any time after etching (including an initial etch or the entirety of the etch) utilizing a conventional photoresist removal process.

The damascene process continues by forming a layer of one of the diffusion barrier materials mentioned above, if the first diffusion barrier liner 12 is present, on a surface of the first interconnect dielectric layer 10 and within each of the openings. This layer of one of the diffusion barrier materials mentioned above can be formed by a deposition process including, for example, CVD, PECVD, atomic layer deposition (ALD), physical vapor deposition (PVD), sputtering, chemical solution deposition or plating. In some embodiments not illustrated, an optional plating seed layer can be formed on top of the layer of diffusion barrier material or it can be formed on a surface of the first interconnect dielectric layer 10 and within each of the openings if the first diffusion barrier liner 12 is not used. The optional plating seed layer can be composed of Cu, a Cu alloy, Ir, an Ir alloy, Ru, a Ru alloy (e.g., TaRu alloy) or any other suitable noble metal or noble metal alloy having a low metal-plating overpotential. Typically, Cu or a Cu alloy plating seed layer is employed, when a Cu metal is to be subsequently formed within the at least one opening. The optional plating seed layer can have a thickness from 2 nm to 80 nm. The optional plating seed layer can be formed by a conventional deposition process including, for example, CVD, PECVD, ALD, or PVD. An electrically conductive metal or electrically conductive metal alloy (both as defined above) is formed into each of the openings formed into the first interconnect dielectric layer 10 and outside of each of the openings. The electrically conductive metal or electrically conductive metal alloy can be formed utilizing a deposition process such as, for example, CVD, PECVD, sputtering, chemical solution deposition or plating. In one embodiment, a bottom-up plating process is employed in forming the electrically conductive metal or electrically conductive metal alloy. Following these various depositions, a planarization process such as, for example, chemical mechanical polishing (CMP) and/or grinding, can be used to remove all overburden materials (i.e., diffusion barrier material, plating seed layer and electrically conductive metal or electrically conductive metal alloy) that are present outside each of the openings that are formed in the first interconnect dielectric layer 10 providing the interconnect level illustrated in FIG. 1.

In the present application, a plurality of electrically conductive wiring structures 14 are formed in the first interconnect dielectric layer 10. In the present application, at least two, more typically, three or more electrically conductive wiring structures 14 are formed. In the present application, each of the electrically conductive wiring structures 14 has a topmost surface that is substantially coplanar with a topmost surface of the first interconnect dielectric layer 10. If the first diffusion barrier liner 12 is present, each of the electrically conductive wiring structures 14 has a topmost surface that is substantially coplanar with a topmost surface of first diffusion barrier liners 12 and a topmost surface of the first interconnect dielectric layer 10.

Referring now to FIG. 2, there is illustrated the exemplary structure shown in FIG. 1 after forming a dielectric capping layer 16 and a second interconnect dielectric layer 18 containing first electrically conductive via structures 22 on top of the interconnect level. In some embodiments, the dielectric capping layer 16 is omitted. In some embodiments and as is illustrated, a second diffusion barrier liner 20 can be present along the sidewalls and, optionally, the bottom wall of the first electrically conductive via structures 22. In some embodiments, the second diffusion barrier liner 20 can be omitted. In the present application, the first electrically conductive via structures 22 are in electrical contact with every other underlying electrically conductive structure 14 as is shown in FIG. 2.

When present, the dielectric capping layer 16 is composed of any dielectric capping material such as, for example, silicon carbide (SiC), silicon nitride (Si₃N₄), silicon dioxide (SiO₂), a carbon doped oxide, a nitrogen and hydrogen doped silicon carbide (SiC(N,H)) or a multilayered stack of at least one of the aforementioned dielectric capping materials. The dielectric capping material is typically compositionally different from the interconnect dielectric materials used in forming the first interconnect dielectric layer 10 and the second interconnect dielectric layer 18. The dielectric capping layer 16 can be formed utilizing a deposition process such as, for example, CVD, PECVD, ALD, chemical solution deposition or evaporation. When present, dielectric capping layer 16 can have a thickness from 10 nm to 100 nm. Other thicknesses that are lesser than 10 nm, or greater than 100 nm may also be used as the thickness of the dielectric capping layer 16.

The second interconnect dielectric layer 18 includes one of the interconnect dielectric materials mentioned above for the first interconnect dielectric layer 10. In some embodiments, the interconnect dielectric material that provides the second interconnect dielectric layer 18 is compositionally the same as the interconnect dielectric material that provides the first interconnect dielectric layer 10. In other embodiments, the interconnect dielectric material that provides the second interconnect dielectric layer 18 is compositionally different from the interconnect dielectric material that provides the first interconnect dielectric layer 10. The second interconnect dielectric layer 18 can be formed utilizing a deposition process such as, for example, CVD, PECVD or spin-on coating. In some embodiments, a planarization process such as, for example, CMP and/or grinding can follow the deposition of the interconnect dielectric material that provides the second interconnect dielectric layer 18.

The optional second diffusion barrier liner 20 can include one of the diffusion barrier materials mentioned above for the optional first diffusion barrier liner 12. In some embodiments, the diffusion barrier material that provides the optional second diffusion barrier liner 20 is compositionally the same as the diffusion barrier material that provides the optional first diffusion barrier liner 12. In other embodiments, the diffusion barrier material that provides the optional second diffusion barrier liner 20 is compositionally different from the diffusion barrier material that provides the optional first diffusion barrier liner 12.

The first electrically conductive via structures 22 that are present in the second interconnect dielectric layer 18 are composed of one of the electrically conductive metals or electrically conductive metal alloys (hereinafter electrically conductive materials) mentioned above for the electrically conductive wiring structures 14. In some embodiments, the electrically conductive material that provides the first electrically conductive via structures 22 is compositionally the same as the electrically conductive material that provides the electrically conductive wiring structures 14. In other embodiments, the electrically conductive material that provides the first electrically conductive via structures 22 is compositionally different from the electrically conductive material that provides the electrically conductive wiring structures 14.

The first electrically conductive via structures 22 and the optional second diffusion barrier liner 20 can be formed utilizing a damascene process as defined above. Note that during the etch utilized in the damascene process, the dielectric capping layer 16 is opened such that a topmost surface of the electrically conductive wiring structures 14 are physically exposed. At this point of the processing, each of the first electrically conductive via structures 22 has a topmost surface that is substantially coplanar with a topmost surface of the second interconnect dielectric layer 18. If the second diffusion barrier liner 20 is present, each of the first electrically conductive via structures 22 has a topmost surface that is substantially coplanar with a topmost surface of second diffusion barrier liners 20 and a topmost surface of the second interconnect dielectric layer 18.

Referring now to FIG. 3, there is illustrated the exemplary structure shown in FIG. 2 after recessing each of the first electrically conductive via structures 22. Recessing of the first electrically conductive via structures 22 can be performed utilizing a recess etching process that is selective in removing the electrically conductive material that provides the first electrically conductive via structures 22. After this recess, the recessed first electrically conductive via structures 22 have a topmost surface that is located beneath a topmost surface of at least the second interlayer dielectric layer 18. It is noted that the recess etch does not remove any portion of the second interlayer dielectric layer 18 or any portion of the optional second diffusion barrier liner 20.

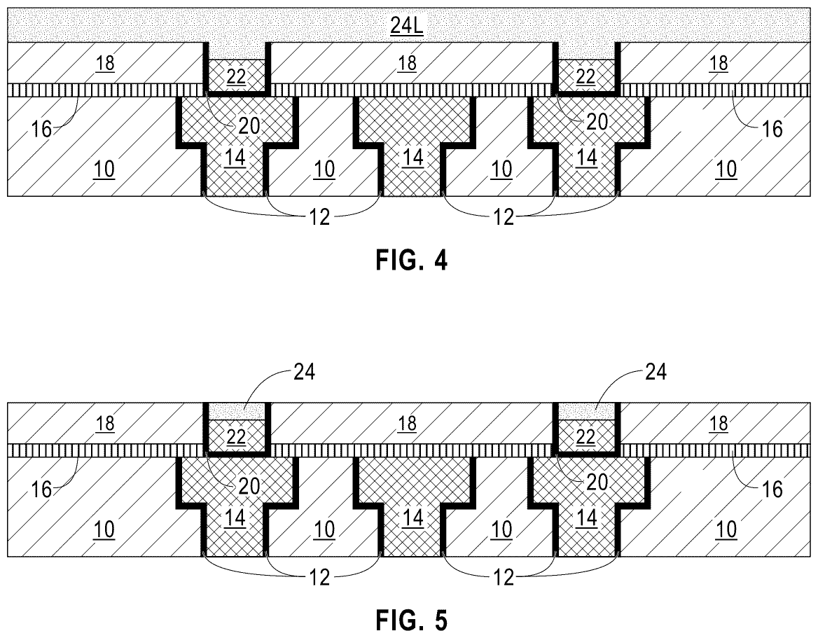

Referring now to FIG. 4, there is illustrated the exemplary structure shown in FIG. 3 after forming a first electrode material layer 24L on a surface of the second interconnect dielectric layer 18 and on a surface of each of the recessed first electrically conductive via structures 22. The first electrode material layer 24L is composed of a conductive electrode material such as, for example, Ta, TaN, Ti, TiN, Ru, RuN, RuTa, RuTaN, Co, CoWP, CoN, W, WN or any combination thereof. The first electrode material layer 24L can be formed by a deposition process such as, for example, sputtering, CVD, PECVD, ALD or PVD.

Referring now to FIG. 5, there is illustrated the exemplary structure shown in FIG. 4 after removing the first electrode material layer 24L from the surface of the second interconnect dielectric layer 18, while maintaining the first electrode material layer 24L on the surface of each of the recessed first electrically conductive via structures 22, wherein the maintained first electrode material layer provides a first electrode 24. Each first electrode 24 that is formed is located directly on a surface of one of the underlying recessed first electrically conductive via structures 22. This removal step of the present application includes a planarization process such as, for example, CMP. At this point of the present application, the first electrodes 24 and the recessed first electrically conductive via structures 22 are both embedded in the second interconnect dielectric layer 18, and each first electrode 24 has a topmost surface that is substantially coplanar with a topmost surface of the second interconnect dielectric layer 18 and, if present, a topmost surface of the second diffusion barrier liner 20. In the illustrated embodiment, the second diffusion barrier liner 20 is present along sidewalls of each bilayer structure of the first electrode 24 and the recessed first electrically conductive via structure 22 that is embedded in the second interconnect dielectric layer 18. It is noted that each first electrode 24 has a sidewall that is vertically aligned to a sidewall of one of the underlying recessed first electrically conductive via structures 22.

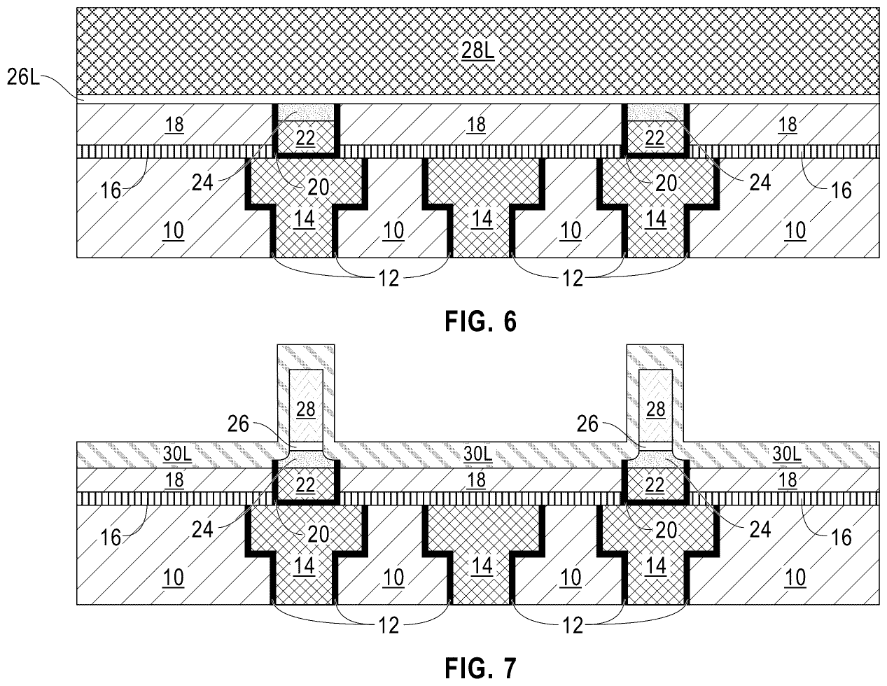

Referring now to FIG. 6, there is illustrated the exemplary structure shown in FIG. 5 after forming a first MTJ stack 26L and a second electrode material layer 28L on top of the second interconnect dielectric layer 18. It is noted that a portion of the first MTJ stack 26L spans across each first electrode 24 and optional second diffusion barrier liner 20 that is present in the second interconnect dielectric layer 18. The first MTJ stack 26L includes at least a tunnel barrier material layer that is located between (i.e., sandwiched between) a magnetic free layer and a magnetic reference (or pinned) layer. For clarity, the drawings of the present application do not separately illustrate the various layers that are present in the first MTJ stack 26L. In some embodiments, the first MTJ stack 26L is a top pinned MTJ structure including, from bottom to top, the magnetic free layer, the tunnel barrier material layer and the magnetic reference layer. In other embodiments, the MTJ stack 26L is a bottom pinned MTJ structure including, from bottom to top, the magnetic reference layer, the tunnel barrier material layer and the magnetic free layer. The first MTJ stack 26L can include other magnetic and non-magnetic materials as are well known to those skilled in the art.

The magnetic free layer of the first MTJ stack 26L has a magnetization that can be changed in orientation relative to the magnetization orientation of the magnetic reference layer. The magnetic free layer can have a thickness from 0.3 nm to 3 nm; although other thicknesses are possible and can be used as the thickness of the magnetic free layer. The magnetic free layer can be composed of a magnetic material or a stack of magnetic materials that are well known to those skilled in the art. In some embodiments, the magnetic free layer includes alloys and/or multilayers of cobalt, iron, alloys of cobalt-iron, nickel, alloys of nickel-iron, and alloys of cobalt-iron-boron. In other embodiments, magnetic free layer is composed of an ordered magnetic alloy. By “ordered magnetic alloy” it is meant a magnetic alloy that has a lattice structure in which atoms of one element occupy particular sites and atoms of at least one other element occupy other sites. In one embodiment, the ordered magnetic alloy that provides the magnetic free layer is a Heusler alloy. Heusler alloys (or compounds) are magnetic intermetallics with a face-centered cubic crystal structure and a composition of XYZ (half-Heuslers) or X₂YX (full-Heuslers), wherein X and Y are transition metals and Z is in the p-block. Exemplary Heusler alloys that can be used in the present application include, but are not limited to, Mn₃Ge, Mn₃Ga, Co₂MnSi, Mn₃Sn, AlMnGe or Mn₃Sb. In another embodiment, the ordered magnetic alloy that provides the magnetic free layer is a L10 alloy. The term “L10 alloy” denotes an intermetallic compound with a body centered tetragonal crystal structure wherein one element occupies the corners of the lattice cell, and the other element occupies the body center. Exemplary L10 alloys that can be used in the present application include, but are not limited to, MnAl or CoFe.

The tunnel barrier material layer of the first MTJ stack 26L is composed of an insulator material and is formed at a thickness sufficient to provide an appropriate tunneling resistance. Exemplary insulator materials for the tunnel barrier material layer include, but are not limited to, magnesium oxide, aluminum oxide, and titanium oxide, or materials of higher electrical tunnel conductance, such as semiconductors or low-bandgap insulators. The thickness of the tunnel barrier material layer will depend on the material selected. In one example, the tunnel barrier material layer can have a thickness from 0.5 nm to 1.5 nm; although other thicknesses are possible as long as the thickness of tunnel barrier material layer provides an appropriate tunneling resistance.

The magnetic reference layer of the first MTJ stack 26L has a fixed magnetization. The magnetic reference layer can be composed of a magnetic metal or magnetic metal alloy (or a stack thereof) that includes one or more magnetic metals exhibiting high spin polarization at the tunnel barrier interface. In alternative embodiments, exemplary magnetic metals for the formation of the magnetic reference layer include iron, nickel, cobalt, chromium, boron, or manganese. Exemplary magnetic metal alloys can include the magnetic metals exemplified by the above for the magnetic reference layer. In another embodiment, the magnetic reference layer can be a multilayer arrangement having (1) a high spin polarization region formed of a metal and/or metal alloy using the metals mentioned above, and (2) a region constructed of a material or materials that exhibit strong perpendicular magnetic anisotropy (strong PMA). Exemplary materials with strong PMA that can be used include a metal such as cobalt, nickel, platinum, palladium, iridium, or ruthenium, and can be arranged as alternating layers. The strong PMA region can also include alloys that exhibit strong intrinsic or bulk (as opposed to interface) PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys can be arranged as alternating layers. In one embodiment, combinations of these materials and regions can also be employed as the magnetic reference layer.

In some embodiments, magnetic reference layer includes a multilayered structure that includes a lower magnetic reference layer, a synthetic anti-ferromagnetic coupling layer and an upper magnetic reference layer. The lower magnetic reference layer can be composed of one of the magnetic materials mentioned above for the magnetic reference layer. The synthetic anti-ferromagnetic coupling layer can be composed of non-magnetic material that can couple in an anti-parallel fashion the lower and upper magnetic layers of this multilayered structure that can be employed as the magnetic reference layer. Exemplary non-magnetic materials that can be used as the synthetic anti-ferromagnetic coupling layer include, but are not limited to, ruthenium (Ru), iridium (Ir) or rhodium (Rh). In one embodiment, the synthetic anti-ferromagnetic coupling layer can have a thickness from 0.2 nm to 1.2 nm; although other thicknesses are possible and can be used as the thickness of the synthetic anti-ferromagnetic coupling layer. The upper magnetic reference layer can be composed of one of the magnetic materials mentioned above for magnetic reference layer. Typically, and in this multilayered structure embodiment, the upper magnetic reference layer is compositionally different from the lower magnetic reference layer.

In some embodiments (not shown), MTJ capping layer can be formed between the topmost layer of the first MTJ stack 26L and the second electrode material layer 28L. When present, the MTJ capping layer can be composed of for example, Nb, NbN, W, WN, Ta, TaN, Ti, TiN, Ru, Mo, Cr, V, Pd, Pt, Rh, Sc, Al or other high melting point metals or conductive metal nitrides. The MTJ capping layer can have a thickness from 2 nm to 25 nm; other thicknesses are possible and can be used in the present application as the thickness of the MTJ capping layer.

The various layers that provide the first MTJ stack 26L can be formed by a deposition process including, but not limited to, CVD, PECVD, PVD, ALD, molecular beam epitaxy (MBE), sputtering or any combination thereof.

The second electrode material layer 28L can include one of the conductive electrode materials mentioned above for the first electrode material layer 24L. In some embodiments, the conductive electrode material that provides the second electrode material layer 28L is compositionally the same as the conductive electrode material that provides the first electrode material layer 24L. In other embodiments, the conductive electrode material that provides the second electrode material layer 28L is compositionally different from the conductive electrode material that provides the first electrode material layer 24L. The second electrode material layer 28L can be formed by a deposition process such as, for example, sputtering, CVD, PECVD, ALD or PVD.

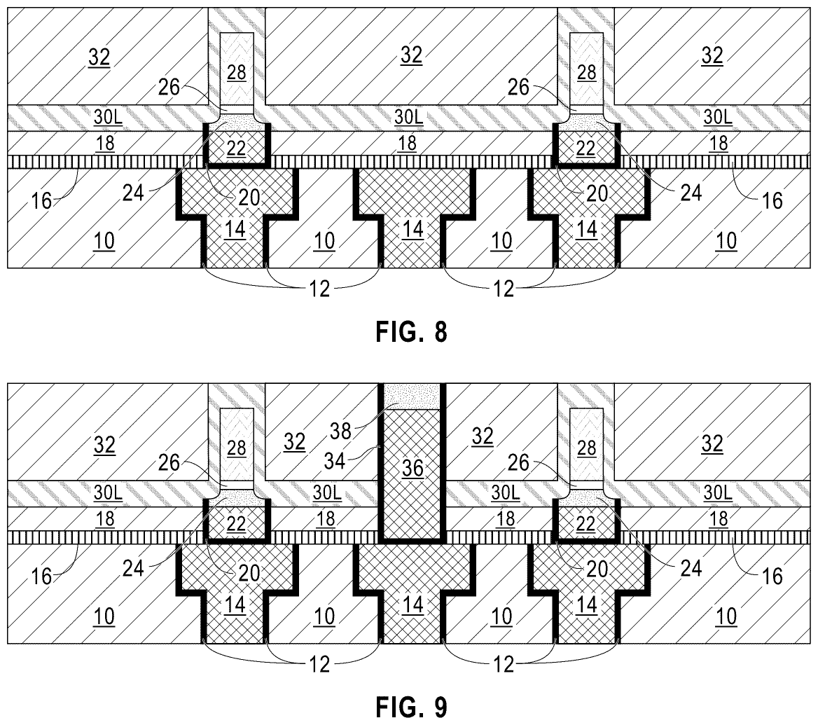

Referring now to FIG. 7, there is illustrated the exemplary structure shown in FIG. 6 after patterning the second electrode material layer 28L and the first MTJ stack 26L to provide second electrodes 28 and first MTJ structures 26, respectively, and forming a first encapsulation layer 30L. The patterning of the second electrode material layer 28L and the first MTJ stack 26L includes lithography and etching. The etching is typically an IBE process; although other types of etching, such as, for example, RIE can be used. In embodiments, the etch is an angled IBE. It is noted that after the pattern of the developed photoresist is transferred to the second electrode material layer 28L, the developed photoresist is removed and each remaining, non-etched, portion of the second electrode material layer 28L, i.e., each second electrode 28, is used as an etch mask during the subsequent etching of the first MTJ stack 26L. Each first MTJ structure 26 includes remaining, i.e., non-etched, portions of the first MTJ stack 26L. Is it noted that during the etch, a portion of the second interconnect dielectric layer 18, the first electrode 24 and, if present, the second diffusion barrier liner 20 can be etched as is shown in FIG. 8. After this patterning process, each first electrode 24 can have a topmost surface that is connected to a sidewall by a beveled surface. After this patterning process, the topmost surface of each first electrode 24 can be located above a topmost surface of the remaining second interconnect dielectric layer 18. Note that each second electrode 28 sits on a topmost surface of one of the underlying first MTJ structures 26, which in turn sits on top of one of the underlying first electrodes 24. Each first electrode 24, first MTJ structure 26, and second electrode 28 combinations forms a first MRAM cell of the structure. The first MRAM cells are located in a first tier of the structure.

After performing the above patterning step that provides the second electrodes 28 and first MTJ structures 26, the first encapsulation layer 30L is formed that laterally surrounds the second electrodes 28, the first MTJ structures 26 and at least an upper portion of the first electrodes 24. The first encapsulation layer 30L is also formed on a surface of the second interconnect dielectric layer 18. The first encapsulation layer 30L is composed of a dielectric material that can provide passivation to each first MRAM cell. In one embodiment, the first encapsulation layer 30L is composed of silicon nitride. In another embodiment, the first encapsulation layer 30L can be composed of a dielectric material that contains atoms of silicon, carbon and hydrogen. In some embodiments, and in addition to atoms of carbon and hydrogen, the dielectric material that provides the first encapsulation layer 30L can include atoms of at least one of nitrogen and oxygen. In other embodiments, and in addition to atoms of silicon, nitrogen, carbon and hydrogen, the dielectric material that provides the first encapsulation layer 30L can include atoms of boron. In one example, the first encapsulation layer 30L can be composed of an nBLOK dielectric material that contains atoms of silicon, carbon, hydrogen, nitrogen and oxygen. In alternative example, the first encapsulation layer 30L can be composed of a SiBCN dielectric material that contains atoms of silicon, boron, carbon, hydrogen, and nitrogen. The first encapsulation layer 30L can be formed by deposition of a continuous layer of the dielectric material that provides the first encapsulation layer 30L. The depositing can include, but is not limited to, CVD, PECVD, PVD, ALD or spin-on coating. The first encapsulation layer 30L can have a thickness from 10 nm to 200 nm. Other thicknesses are possible and can be employed as the thickness of the first encapsulation layer 30L.

Referring now to FIG. 8, there is illustrated the exemplary structure shown in FIG. 7 after forming a third interconnect dielectric layer 32. The third interconnect dielectric layer 32 includes one of the interconnect dielectric materials mentioned above for the first interconnect dielectric layer 10. In some embodiments, the interconnect dielectric material that provides the third interconnect dielectric layer 32 is compositionally the same as the interconnect dielectric material that provides the first interconnect dielectric layer 10 and/or the second interconnect dielectric layer 18. In other embodiments, the interconnect dielectric material that provides the third interconnect dielectric layer 32 is compositionally different from the interconnect dielectric material that provides the first interconnect dielectric layer 10 and/or the second interconnect dielectric layer 18. The third interconnect dielectric layer 32 can be formed utilizing deposition process such as, for example, CVD, PECVD or spin-on coating. A planarization process such as, for example, CMP and/or grinding can follow the deposition of the interconnect dielectric material that provides the third interconnect dielectric layer 32. At this point of the processing, the third interconnect dielectric layer 32 has a topmost surface that is substantially coplanar with a topmost surface of the first encapsulation layer 30L that is present atop the second electrodes 28.

Referring now to FIG. 9, there is illustrated the exemplary structure shown in FIG. 8 after forming a first electrically conductive super via structure 36 and forming a third electrode 38 on a surface of the first electrically conductive super via structure 36. It is noted that the first electrically conductive super via structure 36 has a height that is greater than a height of the recessed first electrically conductive via structures 22. In some embodiments, a third diffusion barrier liner 34 is present along a sidewall of the first electrically conductive super via structure 36 that is subsequently formed. In other embodiments, the third diffusion barrier liner 34 is omitted from the structure. It is noted that although FIG. 9 illustrates the formation of a single first electrically conductive super via structure 36, a plurality of first electrically conductive super via structures would be formed in a laterally alternating manner as the first electrically conductive vias 22.

The optional third diffusion barrier liner 34 can include one of the diffusion barrier materials mentioned above for the optional first diffusion barrier liner 12. In some embodiments, the diffusion barrier material that provides the optional third diffusion barrier liner 34 is compositionally the same as the diffusion barrier material that provides the optional first diffusion barrier liner 12 and/or the optional second diffusion barrier liner 20. In other embodiments, the diffusion barrier material that provides the optional third diffusion barrier liner 34 is compositionally different from the diffusion barrier material that provides the optional first diffusion barrier liner 12 and/or the optional second diffusion barrier liner 20.

The first electrically conductive super via structure 36 is composed of one of the electrically conductive metals or electrically conductive metal alloys (hereinafter electrically conductive materials) mentioned above for the electrically conductive wiring structures 14. In some embodiments, the electrically conductive material that provides the first electrically conductive super via structure 36 is compositionally the same as the electrically conductive material that provides the electrically conductive wiring structures 14 and/or the first electrically conductive via structures 22. In other embodiments, the electrically conductive material that provides the first electrically conductive super via structure 36 is compositionally different from the electrically conductive material that provides the electrically conductive wiring structures 14 and/or first electrically conductive via structures 22.

The first electrically conductive super via structure 36 and the optional third diffusion barrier liner 34 can be formed utilizing a damascene process as defined above. In this damascene process, the etch extends down to a surface of one of the electrically conductive wiring structures 14 that lack one of the recessed first electrically conductive via structures 22 present thereon. Note that during the etch utilized in the damascene process, the dielectric capping layer 16 is again opened such that s topmost surface of at least one of the electrically conductive wiring structures 14 is physically exposed. The optional third diffusion barrier liner 34 and an initial super via structure are then formed in the via openings provided by the above mentioned etch by deposition and planarization.

After forming the initial electrically conductive super via structure and the optional third diffusion barrier liner 34, a recessed etch as defined above in recessing the first electrically conductive via structure 22 is performed to provide the first electrically conductive super via structure 36 illustrated in FIG. 9.

After providing the first electrically conductive super via structure 36, the third electrode 38 is formed utilizing the same basic processing steps as used in forming the first electrode 24. That is, the third electrode 38 is formed by deposition of third electrode material layer (not shown), followed by a planarization process. The third electrode 38 can include one of the conductive electrode materials mentioned above for the first electrode material layer 24L. In some embodiments, the conductive electrode material that provides the third electrode 38 is compositionally the same as the conductive electrode material that provides the first electrode material layer 24L and/or the second electrode material layer 28L. In other embodiments, the conductive electrode material that provides the third electrode 38 is compositionally different from the conductive electrode material that provides the first electrode material layer 24L and/or the second electrode material layer 28L. At this point of the present processing, the third electrode 38 has a topmost surface that is substantially coplanar with a topmost surface of the third interconnect dielectric layer 32. It is noted that the topmost surface of the third electrode 38 is located above a topmost surface of each of the second electrodes 28.

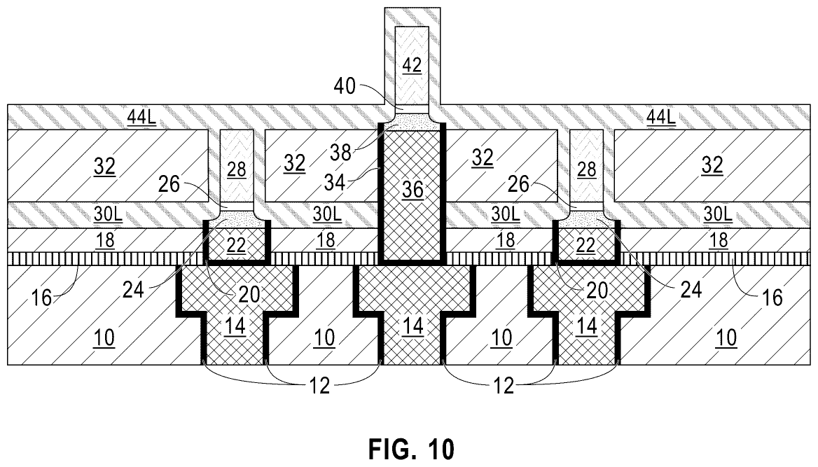

Referring now to FIG. 10, there is illustrated the exemplary structure shown in FIG. 9 after forming a second MTJ structure 40 and a fourth electrode 42 on top of the third electrode 38, and forming a second encapsulation layer 44L. The second MTJ structure 40 includes magnetic and non-magnetic materials as mentioned above for the first MTJ stack 26L. The second MTJ structure 40 includes at least a magnetic reference layer, a tunnel barrier material layer, and a magnetic free layer, each as previously defined above. A top-pinned or bottom pinned MTJ structure configuration is possible for the second MTJ structure 40. Note that the materials and/or MTJ structure configuration that provide the second MTJ structure 40 need not be the same as that of the first MTJ stack 26L.

The fourth electrode 42 can include one of the conductive electrode materials mentioned above for the first electrode material layer 24L. In some embodiments, the conductive electrode material that provides the fourth electrode 42 is compositionally the same as the conductive electrode material that provides the first electrode material layer 24L and/or the second electrode material layer 28L and/or the third electrode material layer. In other embodiments, the conductive electrode material that provides the fourth electrode 42 is compositionally different from the conductive electrode material that provides the first electrode material layer 24L and/or the second electrode material layer 28L and/or the third electrode material layer.

The second MTJ structure 40 and the fourth electrode 42 can be formed utilizing the same process as mentioned above in forming the first MTJ structure 26 and the second electrode 28. That is, the second MTJ structure 40 and a fourth electrode 42 can be formed by deposition, patterning and etching. The etch is again typically an IBE etch including an angled IBE etch as mentioned above. Note that during the etch a portion of the third interlayer dielectric layer 32, the third electrode 38 and, if present, the third diffusion barrier liner 34 can be etched as is shown in FIG. 10. After this patterning process, the third electrode 38 can have a topmost surface that is connected to a sidewall by a beveled surface. After this patterning process, the topmost surface of the third electrode 38 can be located above a topmost surface of the remaining third interconnect dielectric layer 32. Note that the fourth electrode 42 sits on a topmost surface of the underlying second MTJ structure 40, which in turn sits on top of one of the underlying third electrode 38. Each third electrode 38, second MTJ structure 40, and fourth electrode 42 combinations forms a second MRAM cell of the structure. Note that the second MRAM cell is located at a different interconnect level, i.e., second tier, than each of the first MRAMS cells. Each second MRAM cell is horizontally offset from each first MRAM cell.

After the above patterning step that provides the second MRAM cells, the second encapsulation layer 44L is formed that laterally surrounds the second MRAM cell including the fourth electrode 42, the second MTJ structures 40 and at least an upper portion of the third electrode 38. The second encapsulation layer 44L is also formed on a surface of the third interconnect dielectric layer 32 and an on top each of the second electrodes 28. The second encapsulation layer 44L is composed of one of the dielectric materials mentioned above for the first encapsulation layer 30L. The second encapsulation layer 44L can be composed of a compositionally same, or compositionally different, dielectric material as the first encapsulation layer 30L. The second encapsulation layer 44L can be formed utilizing the same processing steps mentioned above in forming the first encapsulation layer 30L. The thickness of the second encapsulation layer 44L is within the range mentioned above for the first encapsulation layer 30L. It is noted that on top of the second electrodes 28 the encapsulation dielectric material would include the dielectric materials of both the first encapsulation layer 30L and the second encapsulation layer 44L. For simplicity, only the second encapsulation layer 44L is shown in directly above each of the second electrodes 28 in FIGS. 10-12.

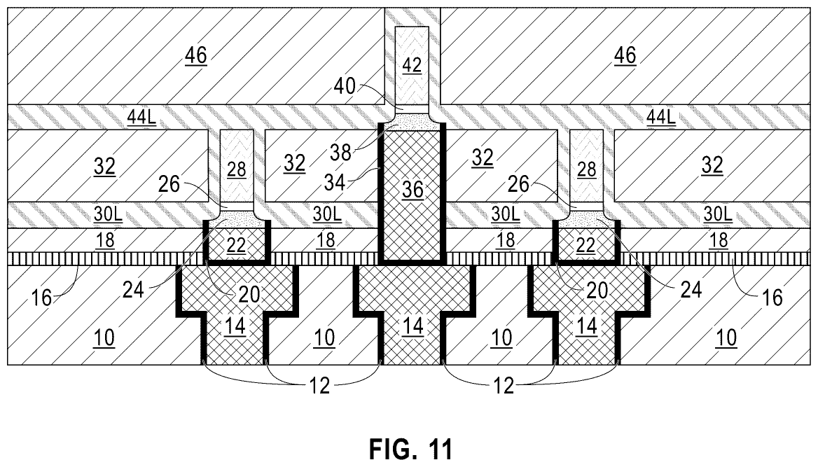

Referring now to FIG. 11, there is illustrated the exemplary structure shown in FIG. 10 after forming a fourth interconnect dielectric layer 46. The fourth interconnect dielectric layer 46 includes one of the interconnect dielectric materials mentioned above for the first interconnect dielectric layer 10. In some embodiments, the interconnect dielectric material that provides the fourth interconnect dielectric layer 46 is compositionally the same as the interconnect dielectric material that provides the first interconnect dielectric layer 10 and/or the second interconnect dielectric layer 18 and/or the third interconnect dielectric layer 32. In other embodiments, the interconnect dielectric material that provides the fourth interconnect dielectric layer 46 is compositionally different from the interconnect dielectric material that provides the first interconnect dielectric layer 10 and/or the second interconnect dielectric layer 18 and/or third interconnect dielectric layer 32. The fourth interconnect dielectric layer 46 can be formed utilizing deposition process such as, for example, CVD, PECVD or spin-on coating. A planarization process such as, for example, CMP and/or grinding can follow the deposition of the interconnect dielectric material that provides the fourth interconnect dielectric layer 46. At this point of the processing, the fourth interconnect dielectric layer 46 has a topmost surface that is substantially coplanar with a topmost surface of the second encapsulation layer 44L that is present atop the fourth electrode 42.

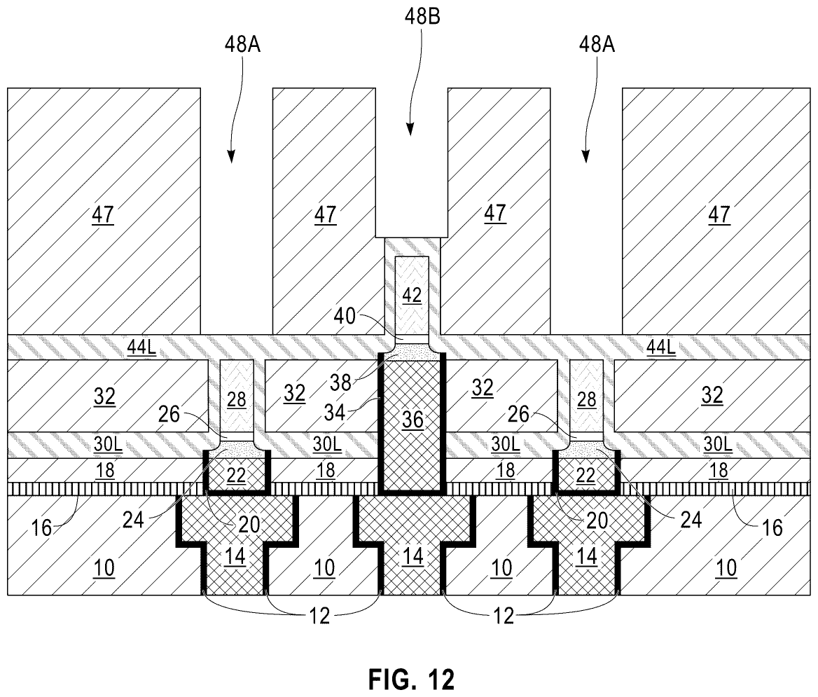

Referring now to FIG. 12, there is illustrated the exemplary structure shown in FIG. 11 after forming additional interconnect dielectric material on the fourth interconnect dielectric layer 46, wherein the additional dielectric material and the fourth dielectric layer 46 collectively provide an uppermost interconnect dielectric layer 47 that covers the entirety of the second encapsulation layer 44L including the portion of the second encapsulation layer 44L that is located on top of the fourth electrode 42, and forming super vias 48A and normal vias 48B in the uppermost interconnect dielectric layer 47.

The additional interconnect dielectric material that is formed on the fourth interconnect dielectric layer 46 is typically composed of the same dielectric material as the fourth interconnect dielectric layer 46. A dielectric material that is compositionally different than the fourth interconnect dielectric layer 46 can however be used as the additional dielectric material. The additional dielectric material can be formed by a deposition process such as, for example, CVD, PECVD or spin-on coating. The electrically conductive super vias 48A and normal vias 48B are each openings that can be formed by lithography and etching. Note the super vias 48A have a height that is greater than a height of the normal vias 48B. The super vias 48A extend down to the portion of the second encapsulation layer 44L that is located on top of the second electrodes 28.

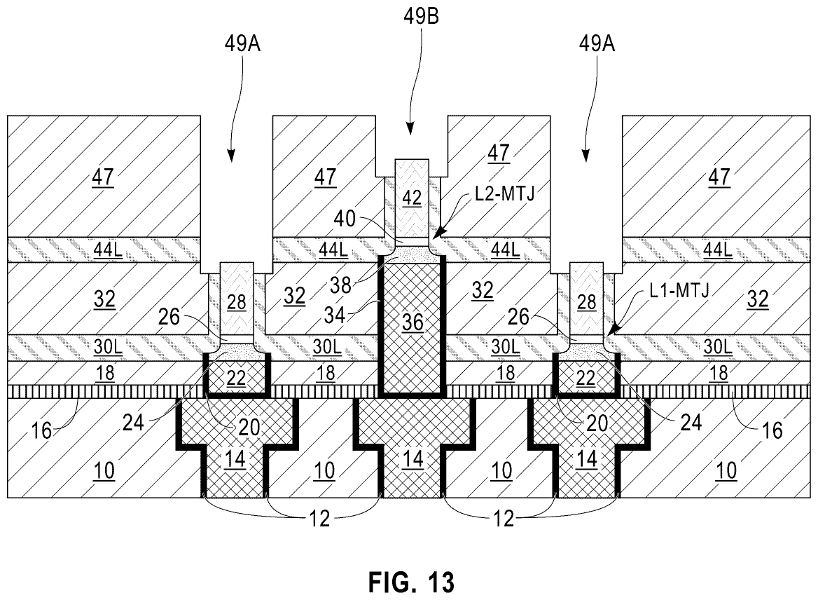

Referring now to FIG. 13, there is illustrated the exemplary structure shown in FIG. 12 after physically exposing each of the second electrodes 28 and the fourth electrodes 42. This step of the present application includes an etching process that is selective in removing the dielectric material that provides the second encapsulation layer 44L and the first encapsulation layer 30L. This etch provides extended super vias 49A that extend down the second electrodes 28, and extended normal vias 49B that extend to the fourth electrode 42. It is noted that this etch not only physically exposes a topmost surface of each of the second electrodes 28 and the fourth electrodes 42, but it also can physically expose an upper sidewall of each of the second electrodes 28 and fourth electrodes 42 as is shown n FIG. 13.

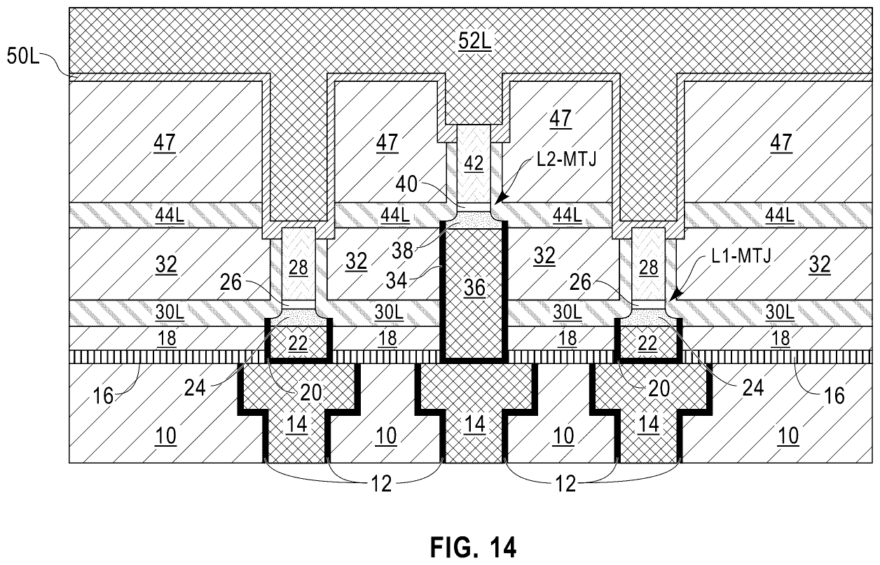

Referring now to FIG. 14, there is illustrated the exemplary structure shown in FIG. 13 after forming an electrically conductive layer 52L on a surface of the uppermost interconnect dielectric layer 47 and on a physically exposed surface of each of the second electrodes 28 and the fourth electrodes (i.e., within each of the extended super vias 49A and the extended normal vias 49B). In some embodiments and as is illustrated in FIG. 14, a diffusion barrier layer 50L can be formed prior to forming the electrically conductive layer 52L. In other embodiments, the diffusion barrier layer 50L can be omitted from the structure.

The optional diffusion barrier layer 50L is composed one of the diffusion barrier materials mentioned above for optional first diffusion barrier liner 12. The diffusion barrier material that provides the optional diffusion barrier layer 50L can be compositionally the same as, or compositionally different from, the diffusion barrier material that provides any of the above mentioned diffusion barrier liners. The optional diffusion barrier layer 50L can be for formed by a deposition process such as, for example, CVD, PECVD, ALD, PVD, sputtering chemical solution deposition or plating. The optional diffusion barrier layer 50L can have a thickness within the range mentioned above for the optional first diffusion barrier liner 12.

The electrically conductive layer 52L is composed of one of the electrically conductive materials (i.e., electrically conductive metals or electrically conductive metal alloys) as mentioned above for the electrically conductive wiring structures 14. The electrically conductive material that provides the electrically conductive layer 52L can be compositionally the same as, or compositionally different from, the electrically conductive material that provides any of the above mentioned electrically conductive wiring structures, including the electrically conductive wiring structures 14, the first electrically conductive via structures 22, and the first electrically conductive super via structures 36.

Referring now to FIG. 15, there is illustrated the exemplary structure shown in FIG. 14 after removing the electrically conductive layer 52L from the surface of the uppermost interconnect dielectric layer 47, while maintaining the electrically conductive layer 52L on the physically exposed surface of each of the second electrodes 28 and the fourth electrodes 42. The maintained electrically conductive layer 52L that is present on top of each second electrode 28 can be referred to a second electrically conductive super via structure 52A and the maintained electrically conductive layer 52L that is present on top of each fourth electrode can be referred to herein as a second electrically conductive via structure 52B. During this removal step used in providing the second electrically conductive super via structures 52A and the second electrically conductive via structures 52B, the optional diffusion barrier layer 50L is removed from atop the uppermost interconnect dielectric layer 47 while maintaining this optional diffusion barrier layer 50L in each of the extended super conductive via openings and extended normal via openings mentioned above. The maintained optional diffusion barrier layer 50L provides an optional fourth diffusion barrier liner 50. The removal process mentioned in providing the exemplary structure shown in FIG. 15 is a planarization process such as, for example, CMP.

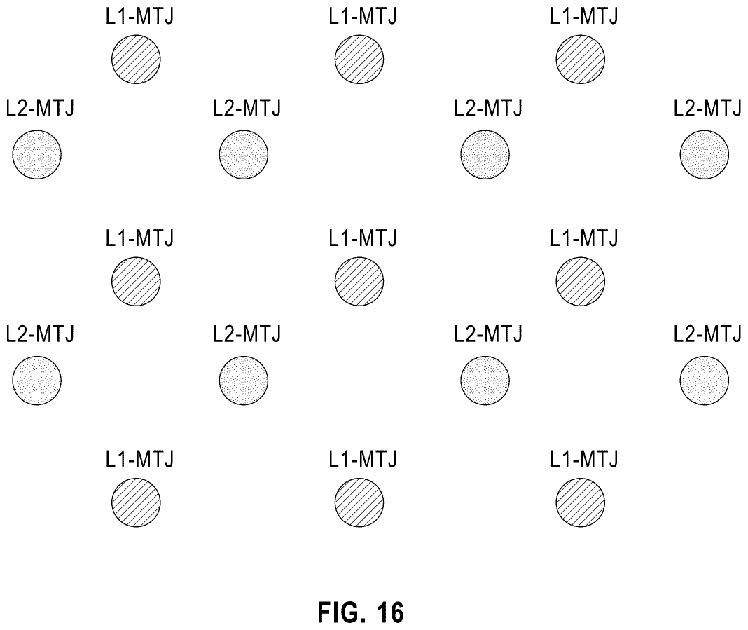

In the present application, each first MRAM cell is located in a first tier of the structure, while each second MRAM cell is located at a second tier of the structure. In FIG. 15 (and FIG. 16 to follow), L1-MTJ denotes the first tier MRAM cells (including first electrode 24, first MTJ structure 26 and second electrode 28), while L2-MTJ denotes the second tier MRAM cells (including third electrode 38, second MTJ structure 40 and fourth electrode 42). As is shown in FIG. 15, the second tier is located at a higher interconnect level than the first tier. FIG. 16 shows a MRAM array in accordance with an embodiment of the present application. This drawing shows the top down view of the two tiers of MTJ.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A memory structure comprising:
a first tier comprising a plurality of first magnetoresistive random access memory (MRAM) cells, wherein each first MRAM cell of the plurality of first MRAM cells has a bottom surface in electrical contact with a first electrically conductive via structure and a top surface in electrical contact with a second electrically conductive super via structure; and
a second tier comprising a plurality of second MRAM cells, wherein each second MRAM cell of the plurality of second MRAM cells is located above and horizontally offset from each of the first MRAM cells of the plurality of first MRAM cells, wherein each second MRAM cell of the plurality of second MRAM cells has a bottom surface in electrical contact with a first electrically conductive super via structure and a top surface in electrical contact with a second electrically conductive via structure.

2. The memory structure of claim 1, wherein the first electrically conductive via structure and the first electrically conductive super via structure have bottommost surfaces that are substantially coplanar with each other, and the second electrically conductive super via structure and the second electrically conductive via structure have topmost surfaces that are substantially coplanar with each other.

3. The memory structure of claim 2, wherein a wiring distance provided by a combination of the first electrically conductive via structure and the second electrically conductive super via structure is substantially equal to a wiring distance provided by a combination of the first electrically conductive super via structure and the second electrically conductive via structure.

4. The memory structure of claim 1, wherein each first MRAM cell of the plurality of first MRAM cells comprises a first electrode, a first MTJ structure, and a second electrode.

5. The memory structure of claim 4, wherein the first electrode is in electrical contact with the first electrically conductive via structure, and the second electrode is in electrical contact with the second electrically conductive super via structure.

6. The memory structure of claim 5, wherein each second MRAM cell of the plurality of second MRAM cells comprises a third electrode, a second MTJ structure, and a fourth electrode.

7. The memory structure of claim 6, wherein the third electrode is in electrical contact with the first electrically conductive super via structure, and the fourth electrode is in electrical contact with the second electrically conductive via structure.

8. The memory structure of claim 7, wherein the first electrically conductive via structure is in electrical contact with an electrically conductive wiring structure, and the first electrically conductive super via structure is in electrical contact with another electrically conductive wiring structure.

9. The memory structure of claim 6, wherein the first electrode and the third electrode both have a topmost surface that is connected to a sidewall by a beveled surface.

10. The memory structure of claim 1, wherein the first MTJ structure and the second MTJ structure both comprise a tunnel barrier layer sandwiched between a magnetic reference layer and a magnetic free layer.

11. The memory structure of claim 10, wherein the magnetic free layer is located above the magnetic reference layer.

12. The memory structure of claim 10, wherein the magnetic free layer is located beneath the magnetic reference layer.

13. The memory structure of claim 1, further comprising a diffusion barrier liner present along sidewalls of each of the first electrically conductive via structure, the first electrically conductive super via structure, the second electrically conductive via structure and the second electrically conductive super via structure.

14. The memory structure of claim 1, further comprising a first encapsulation liner located adjacent to each first MRAM cell of the plurality of first MRAM cells.

15. The memory structure of claim 14, further comprising a second encapsulation liner located adjacent to each second MRAM cell of the plurality of second MRAM cells.

16. The memory structure of claim 1, wherein the plurality of first MRAM cells is present in an interconnect layer that differs from the plurality of second MRAM cells.

17. A method of forming a memory structure, the method comprising:
forming an interconnect level having a plurality of electrically conductive wiring structures embedded in an interconnect dielectric layer;
forming a first electrically conductive structure in electrical contact with every other electrically wiring structure of the plurality of electrically conductive wiring structures;
forming a plurality of first magnetoresistive random access memory (MRAM) cells in a first tier, wherein each first MRAM cell of the plurality of first MRAM cells has a bottom surface in electrical contact with one of the first electrically conductive via structures;
forming a first electrically conductive super via structure in electrical contact with electrically conductive wiring structures not including the first electrically conductive via structure present thereon;
forming a plurality of second MRAM cells in a second tier located above the first tier, wherein each second MRAM cell of the plurality of second MRAM cells is located above and horizontally offset from each of the first MRAM cells of the plurality of first MRAM cells; and
forming a plurality of second electrically conductive super via structures in electrical contact with a topmost surface of each first MRAM cell of the plurality of first MRAM cells and a plurality of second electrically conductive via structures in electrical contact with a topmost surface of each second MRAM cell of the plurality of second MRAM cells.

18. The method of claim 17, wherein the first electrically conductive via structure and the first electrically conductive super via structure have bottommost surfaces that are substantially coplanar with each other, and the second electrically conductive super via structure and the second electrically conductive via structure have topmost surfaces that are coplanar with each other.

19. The method of claim 18, wherein a wiring distance provided by a combination of the first electrically conductive via structure and the second electrically conductive super via structure is substantially equal to a wiring distance provided by a combination of the first electrically conductive super via structure and the second electrically conductive via structure.

20. The method of claim 17, wherein each first MRAM cell of the plurality of first MRAM cells comprises a first electrode, a first MTJ structure, and a second electrode.

21. The method of claim 20, wherein the first electrode is in electrical contact with the first electrically conductive via structure, and the second electrode is in electrical contact with the second electrically conductive super via structure.

22. The method of claim 21, wherein each second MRAM cell of the plurality of second MRAM cells comprises a third electrode, a second MTJ structure, and a fourth electrode.

23. The method of claim 22, wherein the third electrode is in electrical contact with the first electrically conductive super via structure, and the fourth electrode is in electrical contact with the second electrically conductive via structure.

24. The method of claim 17, wherein the forming of the plurality of first MRAM cells and the forming of the plurality of second MRAM cells comprises an ion beam patterning process.
